(19) United States
(12) Patent Application Publication
(10) Pub. No.: US 2026/0204489 A1
(43) Pub. Date: Jul. 16, 2026

(54) THIN FILM CAPACITOR, MANUFACTURING METHOD THEREFOR, AND ELECTRONIC CIRCUIT BOARD HAVING THE THIN FILM CAPACITOR

(71) Applicant: TDK Corporation, Tokyo (JP)

(72) Inventors: Yuta WATANABE, Tokyo (JP); Yoshiaki HAYAMIZU, Tokyo (JP); Yuuki ABURAKAWA, Tokyo (JP); Daiki ISHII, Tokyo (JP)

(21) Appl. No.: 19/134,803

(22) PCT Filed: Dec. 27, 2023
(86) PCT No.: PCT/JP2023/046880

§ 371 Date: Jun. 2, 2025

Related U.S. Application Data
(60) Provisional application No. 63/477,461, filed on Dec. 28, 2022.

(51) Int. Cl. H01G 9/028; H01G 9/00; H01G 9/012; H01G 9/052; H05K 1/185; H10W 44/20

(52) U.S. Cl. CPC H01G 9/028; H01G 9/0036; H01G 9/012; H01G 9/052; H05K 1/185; H05K 2201/10015; H10W 44/243

(57) ABSTRACT

A thin film capacitor includes: a dielectric film covering a roughened main surface of a metal foil and having an opening through which the metal foil The seed layer S and metal layer are both made of a metal material, so the seed layer may be regarded as a part of the metal layer. surrounding the opening; a first electrode provided in the region surrounded by the insulating resin and electrically connected to the metal foil through the opening; and a second electrode provided outside the region surrounded by the insulating resin and contacting the dielectric film without contacting the metal foil. The second electrode includes a conductive polymer layer contacting the dielectric film and a metal layer electrically connected to the conductive polymer layer. An insulating resin exists between the conductive polymer layer and the metal layer.

### TECHNICAL FIELD

The present disclosure relates to a thin film capacitor and a manufacturing method therefor and, more particularly, to a thin film capacitor using a metal foil and a manufacturing method therefor. The present disclosure also relates to an electronic circuit board having such a thin film capacitor.

### BACKGROUND ART

IC-mounted circuit boards are commonly mounted with a decoupling capacitor so as to stabilize the potential of a power supply for an IC. As the decoupling capacitor, multilayer ceramic chip capacitor is typically used, and a large number of the multilayer ceramic chip capacitors are mounted on the surface of the circuit board to thereby achieve required decoupling capacitance.

In recent years, a mounting space for a large number of multilayer ceramic chip capacitors may sometimes become insufficient due to miniaturization of a circuit board. To cope with this, a thin film capacitor capable of being embedded in a circuit board is sometimes used in place of the multilayer ceramic chip capacitor (see Patent Documents 1 to 4).

Thin film capacitors described in Patent Documents 1 to 4 are constituted by a metal substrate whose surface is roughened and an upper electrode covering the metal substrate surface through a dielectric film. In the Patent Documents 1 to 4, a conductive polymer is taken as an example of the material of the upper electrode.

### CITATION LIST

### Patent Document

[Patent Document 1] International Publication WO 2015/118901
[Patent Document 2] International Publication WO 2018/092722
[Patent Document 3] International Publication WO 2017/026247
[Patent Document 4] International Publication WO 2017/014020

### DISCLOSURE OF THE INVENTION

### Problem to Be Solved by the Invention

However, the conductive copolymer typically has a low adhesion to a metal material, which poses a problem that peeling is likely to occur at the interface between the conductive polymer and the metal layer.

The present disclosure describes a technology for preventing peeling of a metal layer in a thin film capacitor having a conductive polymer layer.

### Means for Solving the Problem

A thin film capacitor according to an aspect of the present disclosure includes: a metal foil having a roughened main surface; a dielectric film covering the main surface of the metal foil and having an opening through which the metal foil is partially exposed; an insulating resin provided on the main surface of the metal foil and including a first part surrounding the opening; a first electrode provided in the region surrounded by the first part and electrically connected to the metal foil through the opening; and a second electrode provided outside the region surrounded by the first part and contacting the dielectric film without contacting the metal foil. The second electrode includes a conductive polymer layer contacting the dielectric film and a metal layer electrically connected to the conductive polymer layer. The insulating resin further has a second part positioned between the conductive polymer layer and the metal layer.

A method for manufacturing a thin film capacitor according to an aspect of the present disclosure includes: roughening a main surface of a metal foil; forming a dielectric film on the main surface of the metal foil; forming a first opening in the dielectric film to partially expose the metal foil; providing a first insulating resin surrounding the first opening; forming, at the outside of the region surrounded by the first insulating resin, a conductive polymer layer contacting the dielectric film without contacting the metal foil; forming a second insulating resin covering a part of the conductive polymer layer and exposing another part of the conductive polymer layer through a second opening; and forming, in the region surrounded by the first insulating resin, a first metal layer electrically connected to the metal foil through the first opening and forming, on the second insulating resin, a second metal layer electrically connected to the conductive polymer layer through the second opening.

A method for manufacturing a thin film capacitor according to another aspect of the present disclosure includes: roughening a main surface of a metal foil; forming a dielectric film on the main surface of the metal foil; forming a first opening in the dielectric film to partially expose the metal foil; forming a conductive polymer layer contacting the dielectric film without contacting the metal foil; forming, on the conductive polymer layer, an insulating resin having a second opening for exposing the conductive polymer layer and a third opening for exposing the metal foil through the first opening; and forming, on the insulating resin, a first metal layer electrically connected to the metal foil through the first and third openings and a second metal layer electrically connected to the conductive polymer layer through the second opening.

### Advantageous Effects of the Invention

The present disclosure includes a technique where the metal layer contacts the insulating resin formed on the conductive polymer resin, which makes it possible to prevent the metal layer from peeling.

### BRIEF DESCRIPTION OF THE DRAWINGS

FIG. 1 is a schematic cross-sectional view for explaining the structure of a thin film capacitor 1 according to an embodiment of the technology described herein.

FIG. 2 is a schematic diagram illustrating a first example of the relationship between the opening 24 and the metal layer 42.

FIG. 3 is a schematic diagram illustrating a second example of the relationship between the opening 24 and the metal layer 42.

FIG. 4 is a schematic diagram illustrating a third example of the relationship between the opening 24 and the metal layer 42.

FIG. 5 is a schematic diagram illustrating a fourth example of the relationship between the opening 24 and the metal layer 42.

FIG. 6 is a schematic diagram illustrating a first example of the relationship between the insulating resin 22 and the insulating resin 23.

FIG. 7 is a schematic diagram illustrating a second example of the relationship between the insulating resin 22 and the insulating resin 23.

FIG. 8 is a schematic diagram illustrating a third example of the relationship between the insulating resin 22 and the insulating resin 23.

FIG. 9 is a schematic diagram illustrating a fourth example of the relationship between the insulating resin 22 and the insulating resin 23.

FIG. 10 is a schematic diagram illustrating an example in which the insulating resin 22 and the insulating resin 23 are integrated.

FIG. 11 is a process view for explaining a first example of the manufacturing method for the thin film capacitor 1.

FIG. 12 is a process view for explaining a first example of the manufacturing method for the thin film capacitor 1.

FIG. 13 is a process view for explaining a first example of the manufacturing method for the thin film capacitor 1.

FIG. 14 is a process view for explaining a first example of the manufacturing method for the thin film capacitor 1.

FIG. 15 is a process view for explaining a first example of the manufacturing method for the thin film capacitor 1.

FIG. 16 is a process view for explaining a first example of the manufacturing method for the thin film capacitor 1.

FIG. 17 is a process view for explaining a first example of the manufacturing method for the thin film capacitor 1.

FIG. 18 is a process view for explaining a first example of the manufacturing method for the thin film capacitor 1.

FIG. 19 is a process view for explaining a first example of the manufacturing method for the thin film capacitor 1.

FIG. 20 is a process view for explaining a second example of the manufacturing method for the thin film capacitor 1.

FIG. 21 is a process view for explaining a second example of the manufacturing method for the thin film capacitor 1.

FIG. 22 is a process view for explaining a second example of the manufacturing method for the thin film capacitor 1.

FIG. 23 is a process view for explaining a second example of the manufacturing method for the thin film capacitor 1.

FIG. 24 is a process view for explaining a second example of the manufacturing method for the thin film capacitor 1.

FIG. 25 is a schematic cross-sectional view illustrating an electronic circuit board having a configuration in which a thin film capacitor 1 is embedded in a multilayer substrate 100.

FIG. 26 is a schematic cross-sectional view illustrating an electronic circuit board having a configuration in which a thin film capacitor 1 is mounted on the surface of a multi-layer substrate 300.

FIG. 27 is a table showing the simulation results.

### MODE FOR CARRYING OUT THE INVENTION

Hereinafter, preferred embodiments of the present invention will be described in detail with reference to the accompanying drawings.

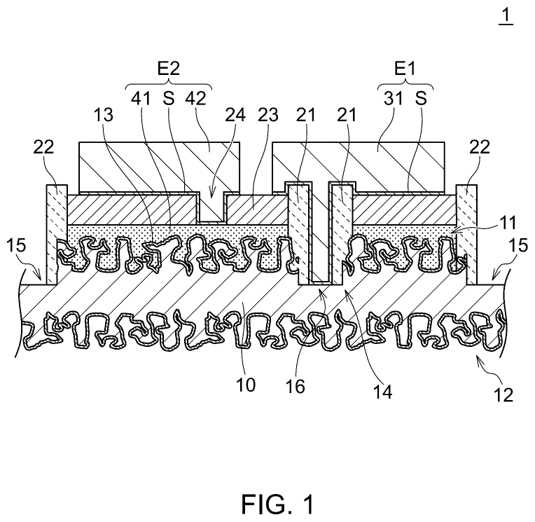

FIG. 1 is a schematic cross-sectional view for explaining the structure of a thin film capacitor 1 according to an embodiment of the technology described herein.

As illustrated in FIG. 1, the thin film capacitor 1 according to the present embodiment includes a metal foil 10 and electrodes E1 and E2 formed on a main surface 11 as the upper surface of the metal foil 10. The metal foil 10 is made of Al (aluminum), for example. The main surface 11 of the metal foil 10 is roughened. A main surface 12 of the metal foil 10 facing away from the main surface 11 may also be roughened. The center portion of the metal foil 10 in the thickness direction thereof is not roughened. A dielectric film 13 is formed on the roughened main surfaces 11 of the metal foil 10. The dielectric film 13 may also be formed on the main surface 12 as the lower surface of the metal foil 10. The dielectric film 13 may be made of, for example, aluminum oxide.

A ring-shaped or polygonal annular insulating resin 21 and an insulating resin 22 extending along the outer periphery of the main surface 11 are formed on the main surface 11 of the metal foil 10. The insulating resin 21 constitutes a first part of the entire insulating resin. The insulating resins 21 and 22 may be integral with each other. In the region surrounded by the insulating resin 21, a trench 14 is formed in the metal foil 10. The trench 14 penetrates the dielectric film 13. This forms an opening 16 in the dielectric film 13 at a portion overlapping the trench 14, and the metal foil 10 is exposed through the opening 16. The other region is covered with the dielectric film 13 with the roughened main surface 11 of the metal foil 10 not exposed. A trench 15 may be formed outside the region surrounded by the insulating resin 22. The metal foil 10 may be exposed to the bottom portion of the trench 15.

A paste or liquid conductive polymer layer 41 is formed outside the region surrounded by the insulating resin 21 but inside the region surrounded by the insulating resin 22. The conductive polymer layer 41 does not contact the metal foil 10 but contacts the dielectric film 13 covering the roughened main surface 11 of the metal foil 10 without contacting the metal foil 10.

The surface of the conductive polymer layer 41 is covered with the insulating resin 23. The insulating resin 23 constitutes a second part of the entire insulating resin. The insulating resin 23 has an opening 24, through which the conductive polymer layer 41 is exposed without being covered with the insulating resin 23. In other words, the entire surface of the conductive polymer layer 41 except for a portion at which the opening 24 is formed is covered with the insulating resin 23. The insulating resin 23 may be constituted by the same insulating material as that of the insulating resins 21 and 22 or by different insulating material from that of the insulating resin 21 and 22. When the insulating resins 21, 22 and the insulating resin 23 are constituted by mutually different resin materials, an interface is generated between the insulating resins 21, 22 and the insulating resin 23. In this case, as the insulating material constituting the insulating resins 21, 22, one having high adhesion to the dielectric film 13 may be used and, as the insulating material constituting the insulating resin 23, one having high adhesion to a metal material may be used. For example, there may be a case where the main material of the insulating resins 21, 22 and that of the insulating resin 23 are different, and there may be a case where the insulating resins 21, 22 and the insulating resin 23 have the same main material but contain different fillers. An example in which different main materials are used may be a case where the insulating resins 21, 22 have an epoxy resin as the main material and the insulating resin 23 has a polyimide-based resin as the main material or vice versa. An example in which different fillers are used may be a case where the filler contained in the insulating resins 21, 22 and the filler contained in the insulating resin 23 are different in shape (e.g., one has a needle shape, and the other has a sphere shape) and a case where the filer contained in the insulating resins 21, 22 and the filler contained in the insulating resin 23 are different in content (one has a content of 0%, and the other has a content of 50%).

Metal layers 31 and 42 are provided on the surface of the insulating resin 23 through a seed layer S. The metal layer 31 is electrically connected to the metal foil 10 through the opening 16 positioned at the region surrounded by the insulating resin 21. The metal layer 42 is connected to the conductive polymer layer 41 through the opening 24. The seed layer S and metal layer 31 constitute a first electrode E1. The conductive polymer layer 41, seed layer S, and metal layer 42 constitute a second electrode E2. This allows the electrodes E1 and E2 to function as a pair of capacitive electrodes facing each other through the dielectric film 13. For example, the electrode E1 constitutes a lower electrode, and the electrode E2 constitutes an upper electrode.

The material of the metal layers 31 and 42 may be a metal material such as copper, nickel, gold, or an alloy thereof. The metal layers 31 and 42 may have a structure in which these metal materials are laminated. The material of the seed layer S is preferably a material having a barrier function capable of preventing diffusion of copper or the like contained in the metal layers 31 and 42, having high adhesion to the metal foil 10 and conductive polymer layer 41, and causing no damage to the conductive polymer layer 41. The seed layer S and metal layer 31 are both made of a metal material, so the seed layer S may be regarded as a part of the metal layer 31. Similarly, the seed layer S and metal layer 42 are both made of a metal material, so the seed layer S may be regarded as a part of the metal layer 42.

Metal materials such as the seed layer S and metal layer 42 typically have a low adhesion to the conductive polymer layer 41. However, in the present embodiment, the surface of the conductive polymer layer 41 is covered with the insulating resin 23, and contact between the conductive polymer layer 41 and the metal material is limited to the opening 24. Thus, by using, as the material of the insulating resin 23, an insulating material having a higher adhesion to a metal material than the conductive polymer layer 41, it is possible to prevent peeling of the metal layer 42.

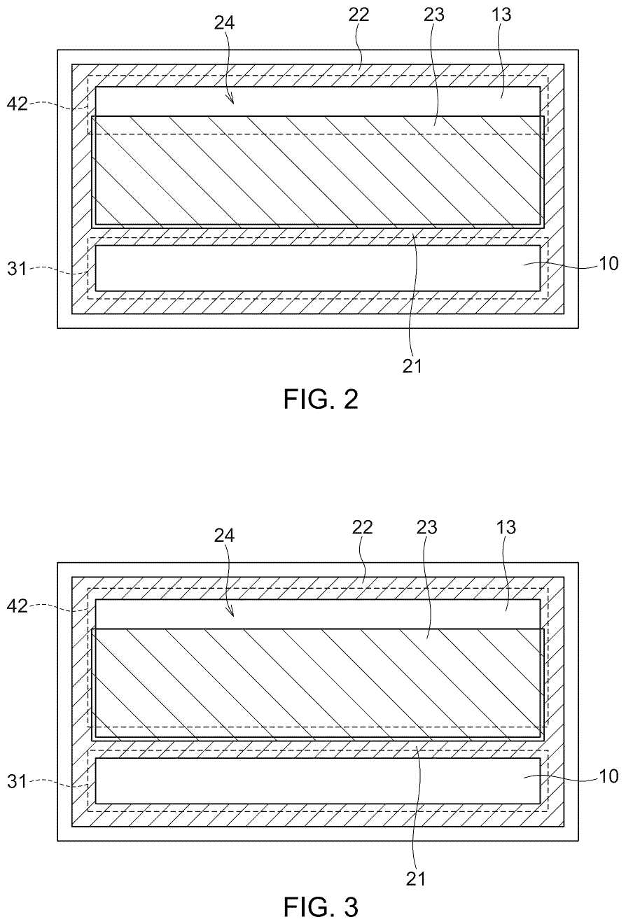

The metal layer 42 may be provided only in and around the opening 24 as illustrated in a schematic view of FIG. 2, or may be provided so as to cover the opening 24 and substantially the entire insulating resin 23 as illustrated in a schematic view of FIG. 3. In the example illustrated in FIGS. 2 and 3, a part of the metal layer 42 is formed also on the upper surface of the insulating resin 22. In the example illustrated in FIG. 3, the area of the surface of the metal layer 42 (seed layer S) that contacts the insulating resin 23 is larger than the area thereof that contacts the conductive polymer layer 41. This prevents peeling of the metal layer 42 more effectively.

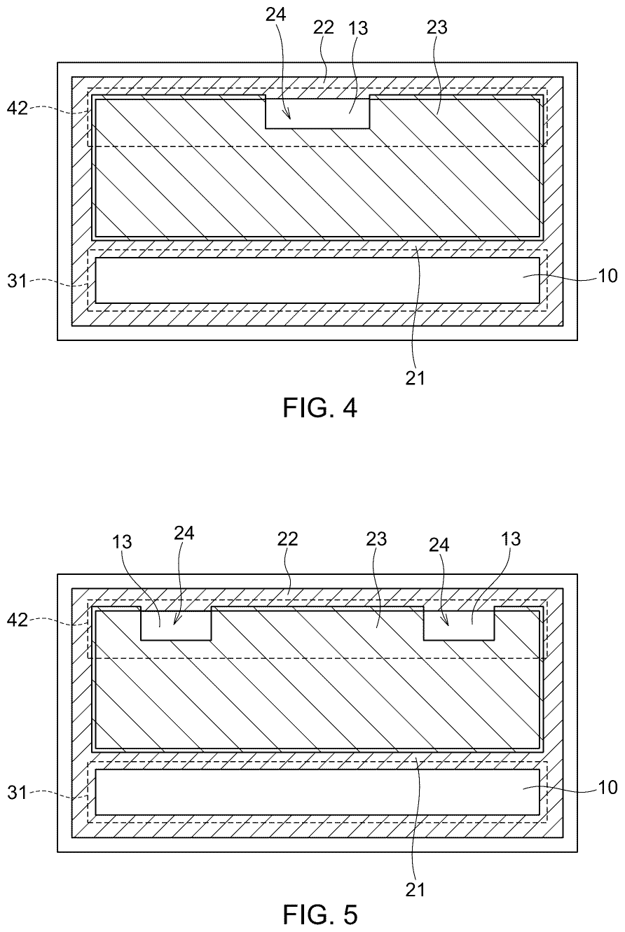

Further, the size of the opening 24 may be reduced as illustrated in a schematic view of FIG. 4, or a plurality of openings 24 may be formed as illustrated in a schematic view of FIG. 5. When the size of the opening 24 is reduced as illustrated in FIG. 4, the contact area between the insulating resin 23 and the metal layer 42 (seed layer S) can be increased. Further, when the plurality of openings 24 are formed as illustrated in FIG. 5, the metal layer 42 is electrically connected to the conductive polymer layer 41 at a plurality of positions, so that ESR is reduced.

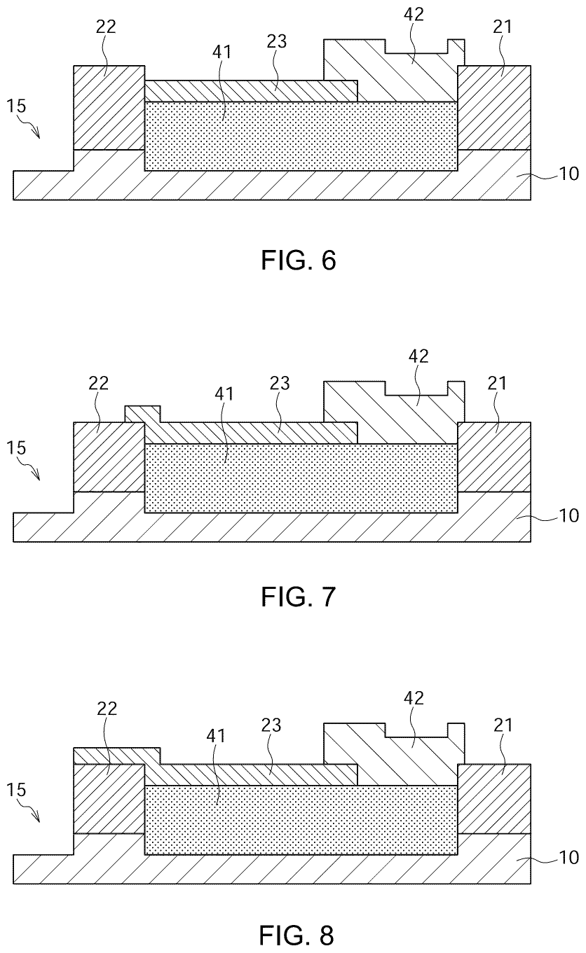

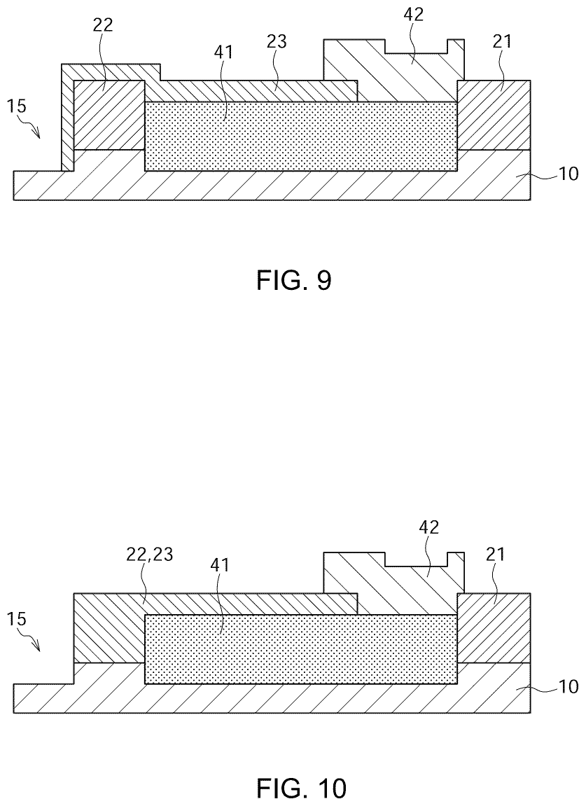

As illustrated in a schematic view of FIG. 6, the upper surface position of the insulating resin 23 may be lower than the upper surface positions of the insulating resins 21 and 22. In this case, the upper surfaces of the insulating resins 21 and 22 are not covered with the insulating resin 23. Alternatively, as illustrated in a schematic view of FIG. 7, the upper surface of the insulating resin 22 may be partially covered with the insulating resin 23. Although not illustrated, the upper surface of the insulating resin 21 may also be partially covered with the insulating resin 23. Alternatively, as illustrated in a schematic view of FIG. 8, substantially the entire upper surface of the insulating resin 22 may be covered with the insulating resin 23. Although not illustrated, substantially the entire upper surface of the insulating resin 21 may also be covered with the insulating resin 23. Further alternatively, as illustrated in i a schematic view of FIG. 9, the insulating resin 23 may extend beyond the insulating resin 23 and reach the trench 15.

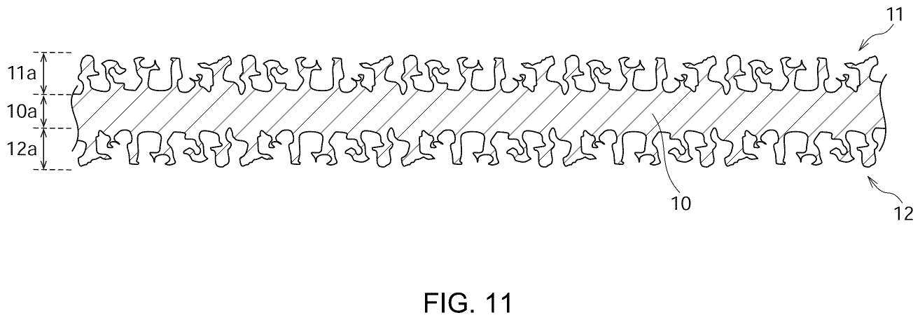

Alternatively, as illustrated in a schematic view of FIG. 10, the insulating resins 22 and 23 may be integral with each other. Although not illustrated, the insulating resins 21 and 23 may also be integral with each other. When the insulating resins 21 and 23 are integral with each other, the insulating resin 21 constitutes the first part of the entire insulating resin, and the insulating resin 23 constitutes the second part of the entire insulating resin. When the insulating resins 21 and 23 are integral with each other, no interface exists therebetween.

The thin film capacitor 1 according to the present embodiment can be used as a decoupling capacitor when being embedded in a multilayer substrate.

The following describes an example of a manufacturing method for the thin film capacitor 1.

FIGS. 11 to 19 are process views for explaining a first example of the manufacturing method for the thin film capacitor 1.

First, the metal foil 10 made of aluminum with thickness of about 50 μm is prepared, and the main surfaces 11 and 12 are etched for roughening (FIG. 11). In place of roughening the flat metal foil 10, the metal foil 10 may be formed by sintering metal powder. As a result, there are formed, in the metal foil 10, a porous layer 11a positioned on the main surface 11 side and a porous layer 12a positioned on the main surface 12 side. A non-porous layer 10a, which is not subjected to roughening, is positioned between the porous layers 11a and 12a. At this time, it is sufficient to apply roughening to at least the main surface 11 positioned on the upper surface side, and the main surface 12 positioned on the lower surface side may not necessarily be roughened; however, roughening both the main surfaces 11 and 12 can prevent warpage of the metal foil 10. The main surface 11 is preferably etched under a condition that the surface area thereof is increased as much as possible. When both the main surfaces 11 and 12 are roughened, they may be etched under different etching conditions. For example, the main surface 12 may be etched under a condition that adhesion to the multilayer substrate is enhanced as much as possible.

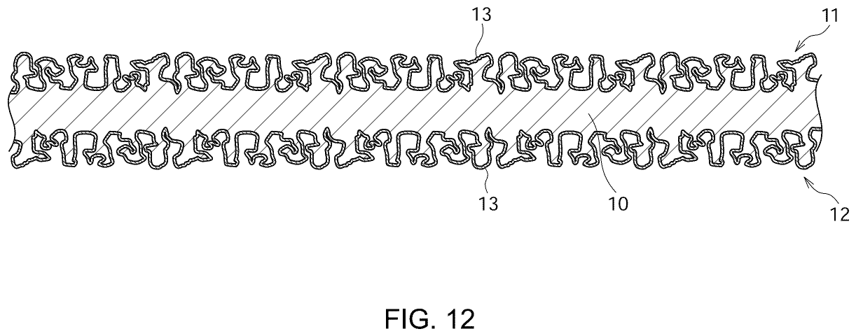

Then, the dielectric film 13 is formed on the surface of the metal foil 10 (FIG. 12). The dielectric film 13 may be formed through oxidation of the metal foil 10 or using a film forming method excellent in coverage performance, such as an ALD method, a CVD method, or a mist CVD method. Examples of the material of the dielectric film 13 include Al₂O₃, TiO₂, Ta₂O₅, and SiNx. Amorphous may be used as the material of the dielectric film 13. In this case, the composition ratio of the dielectric film 13 is not always the same as the composition ratio described above. At this time, it is sufficient to form the dielectric film 13 on at least the main surface 11, and the dielectric film 13 may not necessarily be formed on the main surface 12; however, forming the dielectric film 13 also on the main surface 12 can provide an insulating property to the main surface 12.

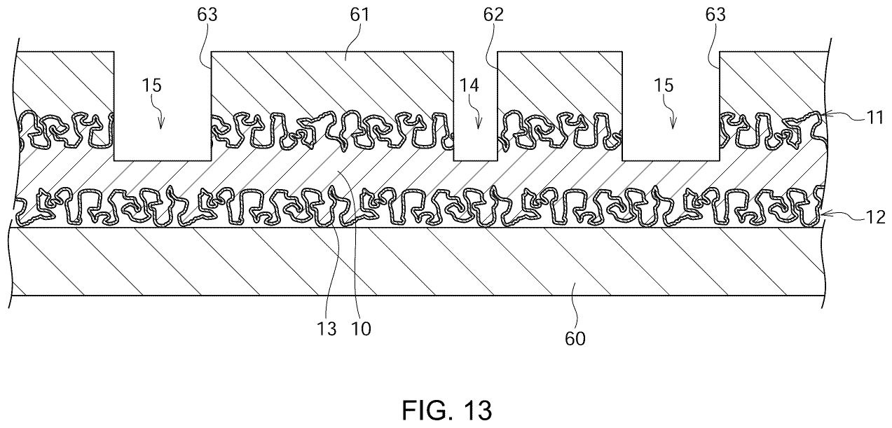

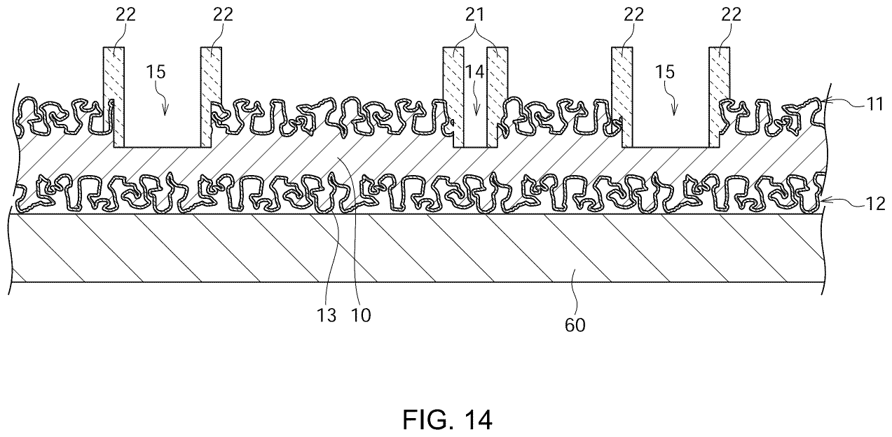

Then, after a support substrate 60 is stuck to the main surface 12 side of the metal foil 10, a photosensitive resist is formed on the main surface 11 of the metal foil 10, followed by exposure and development, to form a patterned resist 61 (FIG. 13). The resist 61 has openings 62 and 63. The resist may be a positive type or a negative type. Subsequently, the dielectric film 13 and metal foil 10 are etched through the resist 61 to form the trenches 14 and 15 at respectively corresponding openings 62 and 63. As a result, the non-porous layer 10a of the metal foil 10 is exposed to the bottom portions of the trenches 14 and 15.

Then, after removal of the resist 61 by ashing or the like, the insulating resins 21 and 22 are formed on the main surface 11 of the metal foil 10 (FIG. 14). The insulating resins 21 and 22 can be formed by a photolithography patterning method, a screen printing method, a gravure printing method, an inkjet method, or the like. The insulating resin 21 is provided along the trench 14, and the insulating resin 22 is provided along the trench 15.

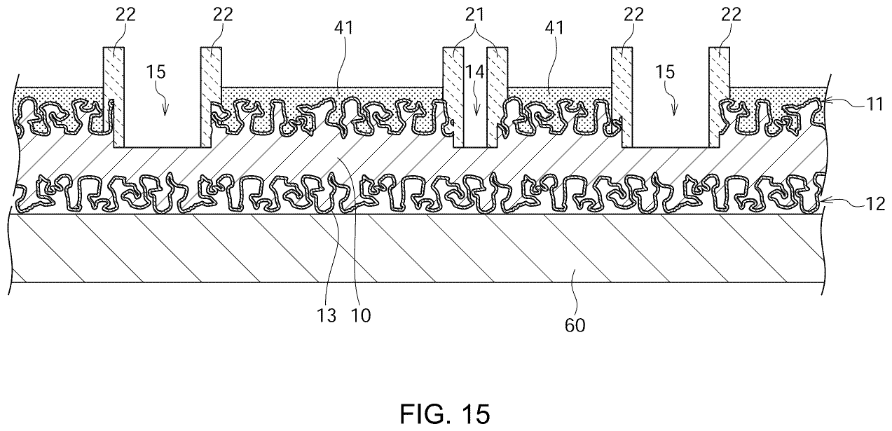

Then, the conductive polymer layer 41 in a paste or liquid form made of a conductive polymer material is formed in the region surrounded by the insulating resin 22, outside the region surrounded by the insulating resins 21 and 22 (FIG. 15). The conductive polymer layer 41 is in a paste or liquid form and is thus filled up to the bottom portion of the porous layer 11a due to capillary action. As a result, the conductive polymer layer 41 contacts the dielectric film 13 without contacting the metal foil 10.

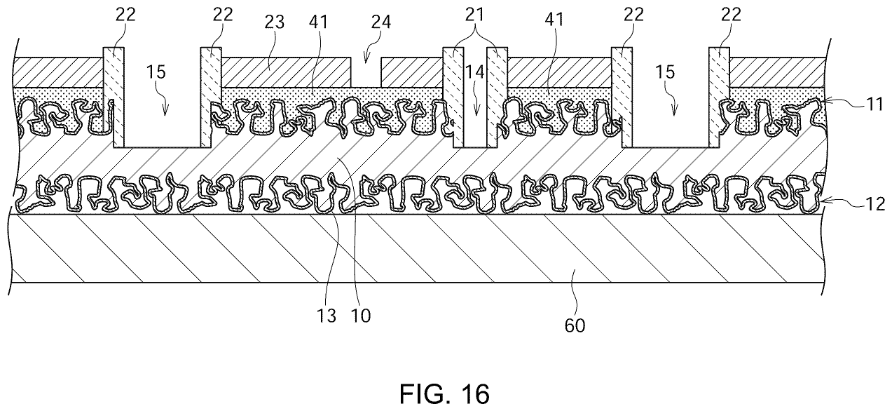

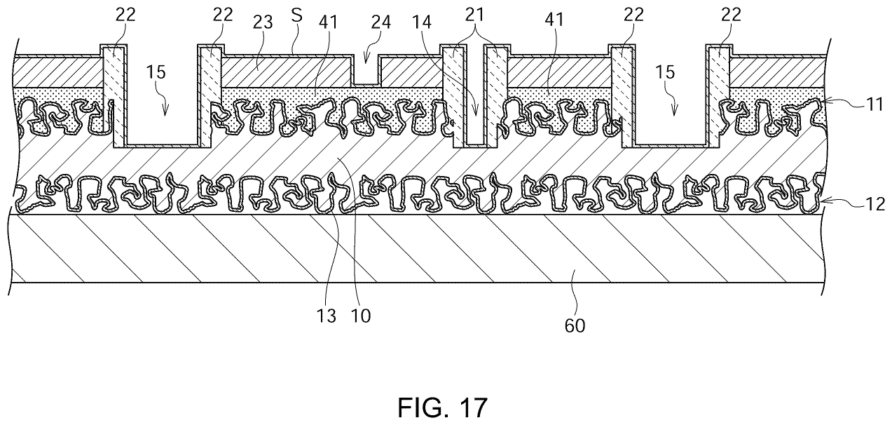

Then, the insulating resin 23 is formed on the surface Of the conductive polymer layer 41 (FIG. 16). The insulating resin 23 can be formed using the same method as for the insulating resins 21 and 22. At this time, the entire surface of the conductive polymer layer 41 is not covered with the insulating resin 23, but the opening 24 for exposing the conductive polymer layer 41 is formed.

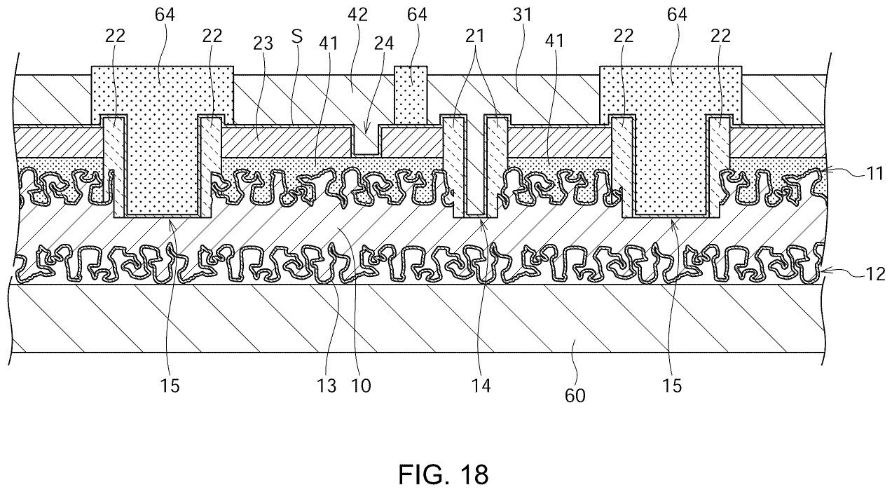

Then, a sputtering method or the like is used to form the seed layer S on the entire surface on the main surface 11 side (FIG. 17). Before forming the seed layer S, a residue remaining on the surface may be removed using a reverse sputtering method or the like. Subsequently, a photosensitive liquid resist 64 is applied on the entire surface, followed by exposure and development, to pattern the resist 64 (FIG. 18). A part of the resist 64 is provided between the trench 14 and the opening 24, and another part of the resist 64 is provided so as to fill up the trench 15. In this state, electrolytic plating is performed to form the metal layers 31 and 42. As a result, the metal layer 31 is electrically connected to the metal foil 10 through the seed layer S, and the metal layer 42 is electrically connected to the conductive polymer layer 41 through the seed layer S.

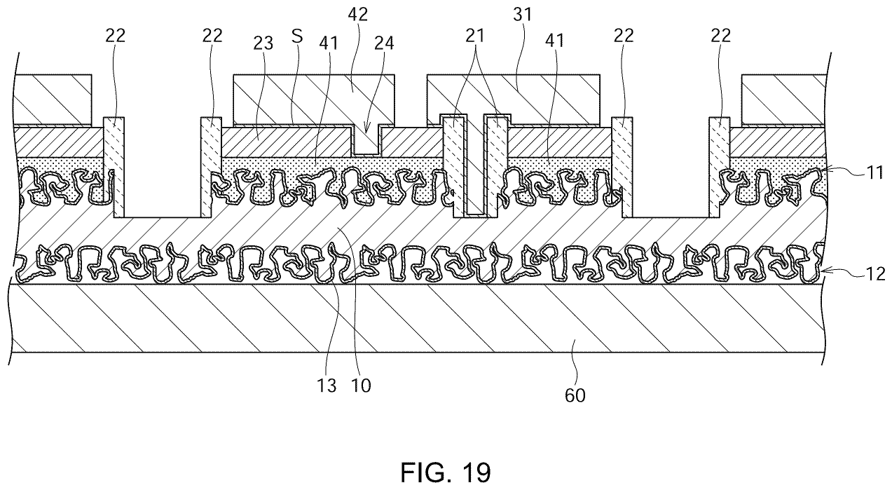

Then, after removal of the resist 64 by ashing or the like, a part of the seed layer s that is exposed as a result of the removal of the resist 64 is removed (FIG. 19). Subsequently, the support substrate 60 is removed after individualization of the metal foil 10, whereby the thin film capacitor 1 illustrated in FIG. 1 is completed.

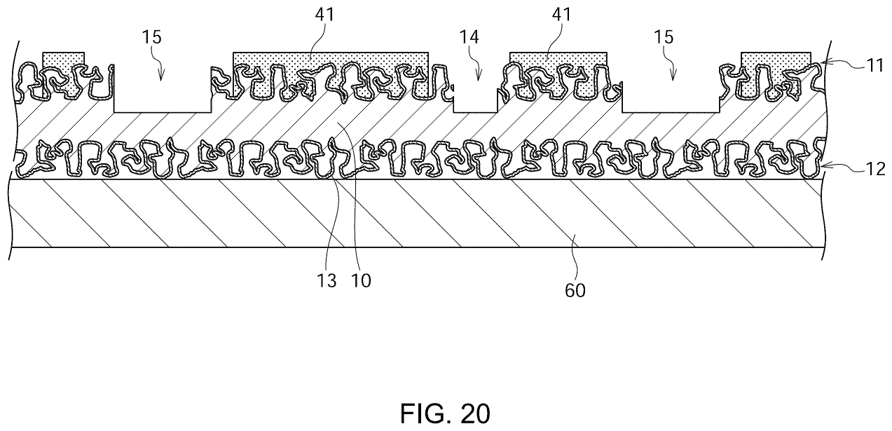

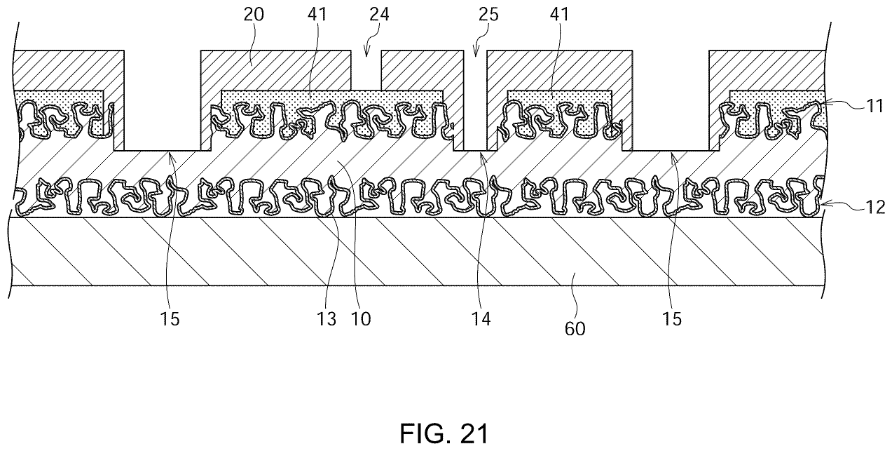

FIGS. 20 to 24 are process views for explaining a second example of the manufacturing method for the thin film capacitor 1.

After completing the processes described using FIGS. 11 to 13, the conductive polymer layer 41 in a paste or liquid form made of a conductive polymer material is formed on the dielectric film 13 covering the roughened main surface 11 of the metal foil 10 (FIG. 20). The conductive polymer layer 41 is in a paste or liquid form and is thus filled up to the bottom portion of the porous layer 11a due to capillary action. As a result, the conductive polymer layer 41 contacts the dielectric film 13 without contacting the metal foil 10; however, the movement of the conductive polymer layer 41 due to the capillary action is stopped at the trenches 14 and 15.

Then, an insulating resin 20 is formed on the surface of the conductive polymer layer 41 (FIG. 21). The insulating resin 20 corresponds to the insulating resins 21 to 23 illustrated in FIG. 1 and can be formed using the Same method as for the insulating resins 21 to 23. At this time, the entire surface of the conductive polymer layer 41 is not covered with the insulating resin 20, but the opening 24 for exposing the conductive polymer layer 41 is formed. Further, the trench 14 is not completely filled up with the insulating resin 20, but a state where the metal foil 10 is exposed to the bottom portion of the trench 14 is maintained.

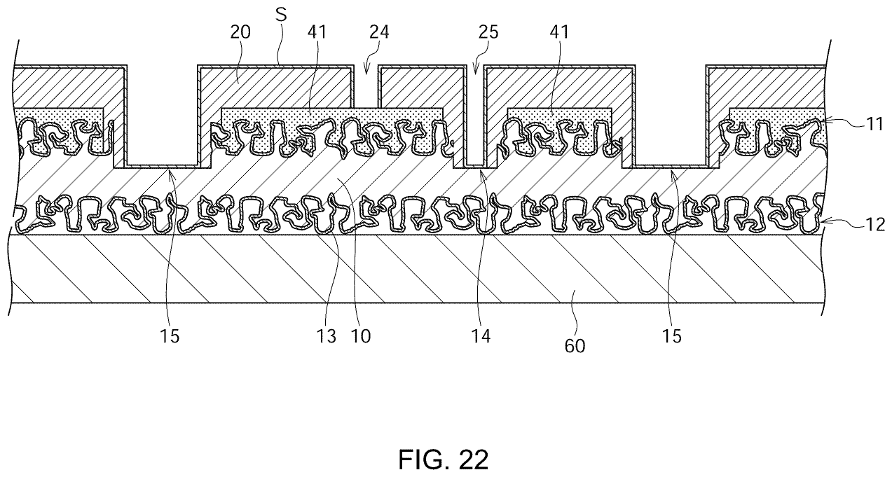

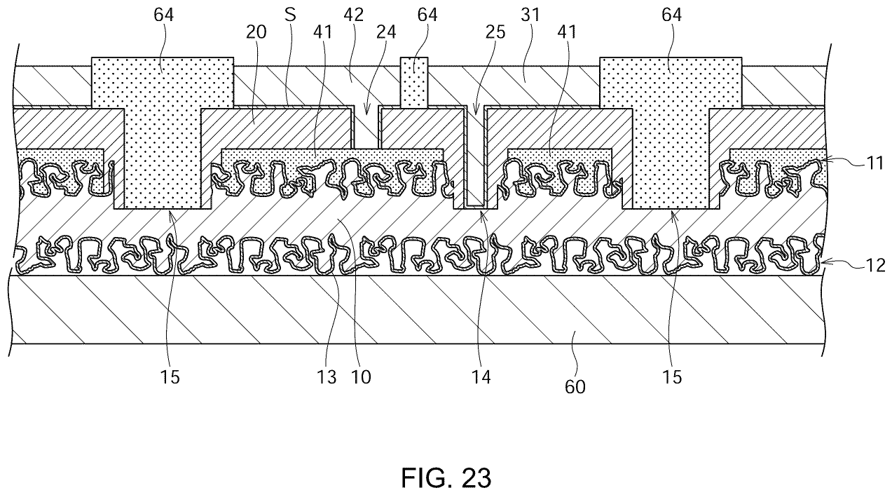

Then, a sputtering method or the like is used to form the seed layer S on the entire surface on the main surface 11 side (FIG. 22). Before forming the seed layer S, a residue remaining on the surface may be removed using a reverse sputtering method or the like. Subsequently, the photosensitive liquid resist 64 is applied to the entire surface, followed by exposure and development, to pattern the resist 64 (FIG. 23). A part of the resist 64 is provided between the trench 14 and the opening 24, and another part of the resist 64 is provided so as to fill up the trench 15. In this state, electrolytic plating is performed to form the metal layers 31 and 42. As a result, the metal layer 31 is electrically connected to the metal foil 10 through the seed layer S, and the metal layer 42 is electrically connected to the conductive polymer layer 41 through the seed layer S.

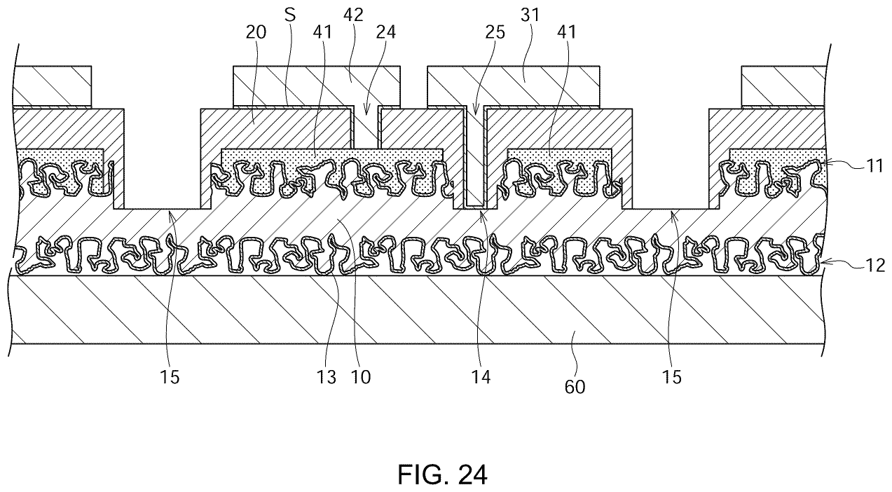

Then, after removal of the resist 64 by ashing or the like, a part of the seed layer S that is exposed as a result of the removal of the resist 64 is removed (FIG. 24). Subsequently, the support substrate 60 is removed after individualization of the metal foil 10, whereby a structure in which the insulating resins 21 to 23 are integrated in the thin film capacitor 1 illustrated in FIG. 1 is completed.

The above-described thin film capacitor 1 may be embedded in a multilayer substrate or mounted on the surface of a multilayer substrate.

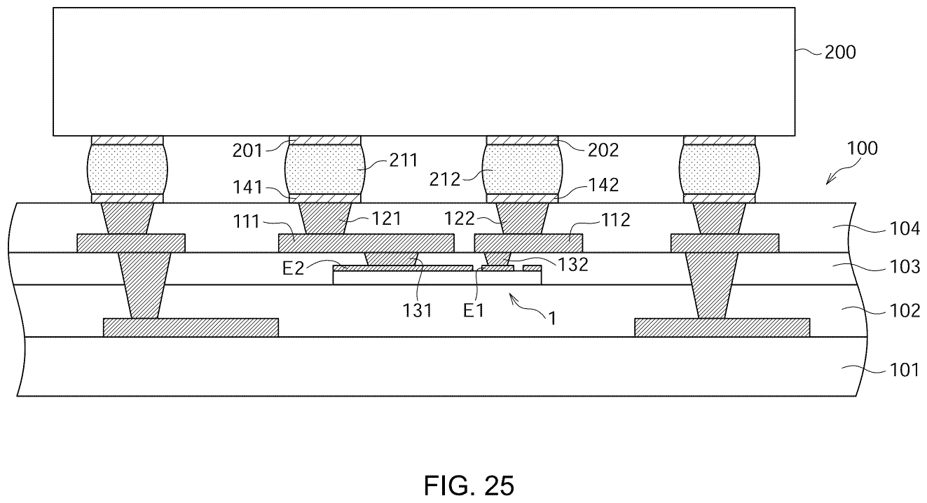

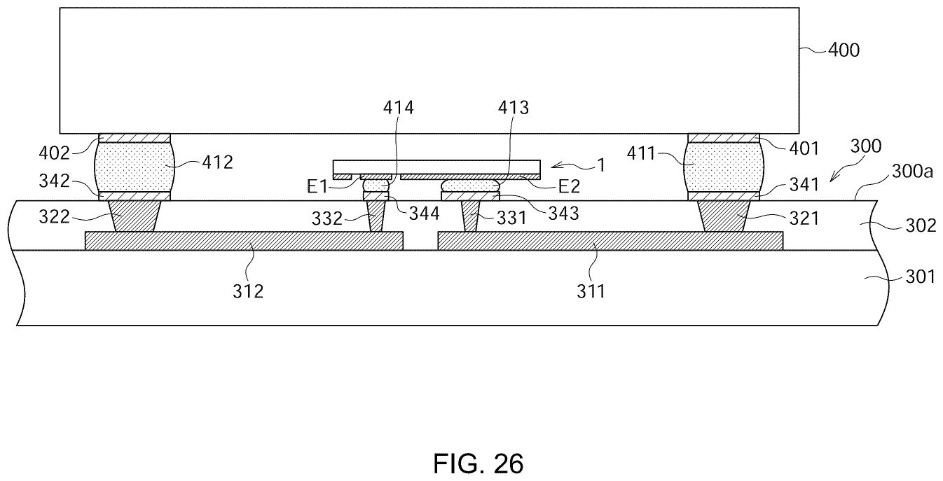

An electronic circuit board illustrated in FIG. 25 has a configuration in which a semiconductor IC 200 is mounted on a multilayer substrate 100. The multilayer substrate 100 includes a plurality of insulating layers including insulating layers 101 to 104 and a plurality of wiring patterns including wiring patterns 111 and 112. The number of the insulating layers is not particularly limited. In the example illustrated in FIG. 25, the thin film capacitor 1 is embedded between the insulating layers 102 and 103. There are provided on the surface of the multilayer substrate 100 a plurality of land patterns including land patterns 141 and 142. The semiconductor IC 200 has a plurality of pad electrodes including pad electrodes 201 and 202. For example, one of the pad electrodes 201 and 202 is a power supply terminal, and the other one thereof is a ground terminal. The pad electrode 201 and land pattern 141 are connected to each other through a solder 211, and pad electrode 202 and land pattern 142 are connected to each other through a solder 212. The land pattern 141 is connected to the electrode E2 of the thin film capacitor 1 through a via conductor 121, the wiring pattern 111, and a via conductor 131. The land pattern 142 is connected to the electrode E1 of the thin film capacitor 1 through a via conductor 122, the wiring pattern 112, and a via conductor 132. With this configuration, the thin film capacitor 1 functions as a decoupling capacitor for the semiconductor IC 200.

An electronic circuit substrate illustrated in FIG. 26 has a configuration in which a semiconductor IC 400 is mounted on a multilayer substrate 300. The multilayer substrate 300 includes a plurality of insulating layers including insulating layers 301 and 302 and a plurality of wiring patterns including wiring patterns 311 and 312. The number of the insulating layers is not particularly limited. In the example illustrated in FIG. 26, the thin film capacitor 1 is surface-mounted on a surface 300a of the multilayer substrate 300. There are provided on the surface 300a of the multilayer substrate 300 a plurality of land patterns including land patterns 341 to 344. The semiconductor IC 400 has a plurality of pad electrodes including pad electrodes 401 and 402. For example, one of the pad electrodes 401 and 402 is a power supply terminal, and the other one thereof is a ground terminal. The pad electrode 401 and land pattern 341 are connected to each other through a solder 411, and pad electrode 402 and land pattern 342 are connected to each other through a solder 412. The land pattern 341 is connected to the electrode E2 of the thin film capacitor 1 through a via conductor 321, the wiring pattern 311, a via conductor 331, the land pattern 343, and a solder 413. The land pattern 342 is connected to the electrode E1 of the thin film capacitor 1 through a via conductor 322, the wiring pattern 312, a via conductor 332, the land pattern 344, and a solder 414. With this configuration, the thin film capacitor 1 functions as a decoupling capacitor for the semiconductor IC 400.

While the preferred embodiment of the present disclosure has been described, the present disclosure is not limited to the above embodiment, and various modifications may be made within the scope of the present disclosure, and all such modifications are included in the present disclosure.

The technology according to the present disclosure includes the following configuration examples but not limited thereto.

A thin film capacitor according to an aspect of the present disclosure includes: a metal foil having a roughened main surface; a dielectric film covering the main surface of the metal foil and having an opening through which the metal foil is partially exposed; an insulating resin provided on the main surface of the metal foil and including a first part surrounding the opening; a first electrode provided in the region surrounded by the first part and electrically connected to the metal foil through the opening; and a second electrode provided outside the region surrounded by the first part and contacting the dielectric film without contacting the metal foil. The second electrode includes a conductive polymer layer contacting the dielectric film and a metal layer electrically connected to the conductive polymer layer. The insulating resin further has a second part positioned between the conductive polymer layer and the metal layer. With this configuration, it is possible to suppress peeling of the metal layer constituting the second electrode.

In the above thin film capacitor, the area of the surface of the metal layer that contacts the second part of the insulating resin may be larger than the area of a surface of the metal layer that contacts the conductive polymer layer. This can enhance adhesion of the metal layer constituting the second electrode.

In the above thin film capacitor, the metal layer may contact the conductive polymer layer at a plurality of positions. This can reduce ESR.

In the above thin film capacitor, the first part of the insulating resin may be made of a first insulating material, and the second part of the insulating resin may be made of a second insulating material different from the first insulating material. This allows materials suitable for the respective first and second parts to be used.

In the above thin film capacitor, the first part and the second part of the insulating resin may be made of the same material. This can enhance adhesion between the first and second parts. In this case, the first part and the second part of the insulating resin may be integral with each other. With this configuration, there exists no interface between the first and second parts, preventing peeling therebetween.

In the above thin film capacitor, an interface may exist between the first part and the second part of the insulating resin. This facilitates product evaluation and analysis.

An electronic circuit board according to an aspect of the present disclosure includes: a substrate having wiring patterns; and a semiconductor IC and the above thin film capacitor provided on the substrate. The first and second electrodes of the thin film capacitor are connected to the semiconductor IC through the wiring patterns. This allows the thin film capacitor to function as a decoupling capacitor for the semiconductor IC.

A method for manufacturing a thin film capacitor according to an aspect of the present disclosure includes: roughening a main surface of a metal foil; forming a dielectric film on the main surface of the metal foil; forming a first opening in the dielectric film to partially expose the metal foil; providing a first insulating resin surrounding the first opening; forming, at the outside of the region surrounded by the first insulating resin, conductive polymer layer contacting the dielectric film without contacting the metal foil; forming a second insulating resin covering a part of the conductive polymer layer and exposing another part of the conductive polymer layer through a second opening; and forming, in the region surrounded by the first insulating resin, a first metal layer electrically connected to the metal foil through the first opening and forming, on the second insulating resin, a second metal layer electrically connected to the conductive polymer layer through the second opening.

A method for manufacturing a thin film capacitor according to another aspect of the present disclosure includes: roughening a main surface of a metal foil; forming a dielectric film on the main surface of the metal foil; forming a first opening in the dielectric film to partially expose the metal foil; forming a conductive polymer layer contacting the dielectric film without contacting the metal foil; forming, on the conductive polymer layer, an insulating resin having a second opening for exposing the conductive polymer layer and a third opening for exposing the metal foil through the first opening; and forming, on the insulating resin, a first metal layer electrically connected to the metal foil through the first and third openings and a second metal layer electrically connected to the conductive polymer layer through the second opening.

### EXAMPLES

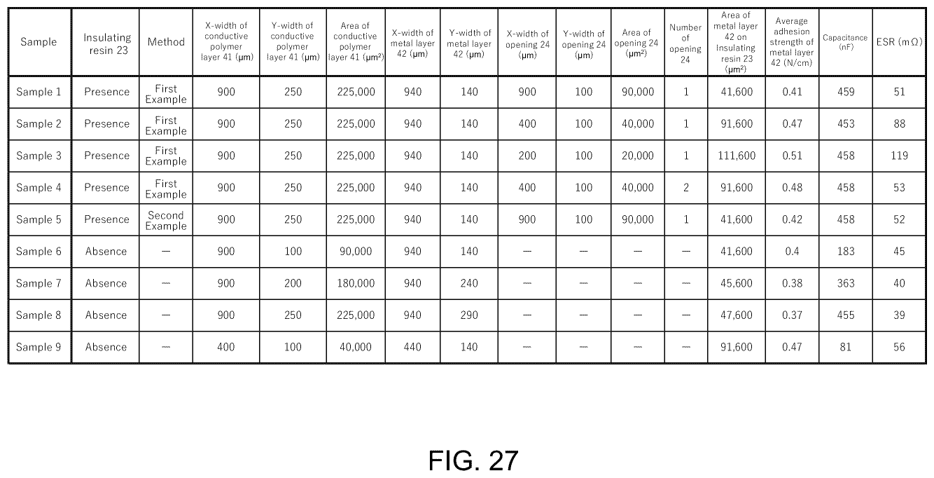

As illustrated in FIG. 27, the average adhesion strength of the metal layer 42, capacitance, and ESR are simulated with a plurality of samples different in terms of the presence/absence of the insulating resin 23, the size of the conductive polymer layer 41, the size of the metal layer 42, and the like assumed. The planar size of each of the samples is 10 mm×5 mm, and ideal capacitance is 2000 nF /mm².

Samples 1 to 5 have the insulating resin 23. Samples 6 to 9 do not have the insulating resin 23. Samples 1 to 4 are assumed to have a structure produced according to the first example of the manufacturing method described using FIGS. 11 to 19. Sample 5 is assumed to have a structure produced according to the second example of the manufacturing method described using FIGS. 11 to 13 and FIGS. 20 to 24. Samples 1 to 3 and 5 each have one opening 24. Sample 4 has two openings 24.

As illustrated in FIG. 27, Samples 1 to 5 having the insulating resin 23 are higher in the average adhesion strength of the metal layer 42 than Samples 6 to 9. Samples 1 to 5 and 8, which have the same sized conductive polymer layer 41, exhibit substantially the same capacitance (exhibit no significant difference). When comparing Samples 2 and 4, in which the areas of the openings 24 are the same, Sample 4 in which the opening 24 is divided in two parts exhibits lower ESR than Sample 2.

### Reference Signs List

1 thin film capacitor
10 metal foil
10a non-porous layer
11, 12 main surface
11a, 12a porous layer
13 dielectric film
14, 15 trench
16 opening
20-23 insulating resin
24, 25 opening
31, 42 metal layer
41 conductive polymer layer
60 support substrate
61 resist
62, 63 opening
64 resist
100 multilayer substrate
101-104 insulating layer
111, 112 wiring pattern
121, 122, 131, 132 via conductor
141, 142 land pattern
200 semiconductor IC
201, 202 pad electrode
211, 212 solder
300 multilayer substrate
300a surface
301, 302 insulating layer
311, 312 wiring pattern
321, 322, 331, 332 via conductor
341-344 land pattern
400 semiconductor IC
401, 402 pad electrode
411-414 solder
E1, E2 electrode
S seed layer

1. A thin film capacitor comprising:
a metal foil having a roughened main surface;
a dielectric film covering the main surface of the metal foil and having an opening through which the metal foil is partially exposed;
an insulating resin provided on the main surface of the metal foil and including a first part surrounding the opening;
a first electrode provided in a region surrounded by the first part and electrically connected to the metal foil through the opening; and
a second electrode provided outside the region surrounded by the first part and contacting the dielectric film without contacting the metal foil,
wherein the second electrode includes a conductive polymer layer contacting the dielectric film and a metal layer electrically connected to the conductive polymer layer, and
wherein the insulating resin further includes a second part positioned between the conductive polymer layer and the metal layer.

2. The thin film capacitor as claimed in claim 1, wherein an area of a surface of the metal layer that contacts the second part of the insulating resin is larger than an area of a surface of the metal layer that contacts the conductive polymer layer.

3. The thin film capacitor as claimed in claim 1, wherein the metal layer contacts the conductive polymer layer at a plurality of positions.

4. The thin film capacitor as claimed in claim 1,
wherein the first part of the insulating resin is made of a first insulating material, and
wherein the second part of the insulating resin is made of a second insulating material different from the first insulating material.

5. The thin film capacitor as claimed in claim 1, wherein the first part and the second part of the insulating resin are made of a same material.

6. The thin film capacitor as claimed in claim 5, wherein the first part and the second part of the insulating resin are integral with each other.

7. The thin film capacitor as claimed in claim 1, wherein an interface exists between the first part and the second part of the insulating resin.

8. A method for manufacturing a thin film capacitor, the method comprising:
roughening a main surface of a metal foil;
forming a dielectric film on the main surface of the metal foil;
forming a first opening in the dielectric film to partially expose the metal foil;
providing a first insulating resin surrounding the first opening;
forming, at an outside of a region surrounded by the first insulating resin, a conductive polymer layer contacting the dielectric film without contacting the metal foil;
forming a second insulating resin covering a part of the conductive polymer layer and exposing another part of the conductive polymer layer through a second opening; and
forming, in the region surrounded by the first insulating resin, a first metal layer electrically connected to the metal foil through the first opening and forming, on the second insulating resin, a second metal layer electrically connected to the conductive polymer layer through the second opening.

9. A method for manufacturing a thin film capacitor, the method comprising:
roughening a main surface of a metal foil;
forming a dielectric film on the main surface of the metal foil;
forming a first opening in the dielectric film to partially expose the metal foil;
forming a conductive polymer layer contacting the dielectric film without contacting the metal foil;
forming, on the conductive polymer layer, an insulating resin having a second opening for exposing the conductive polymer layer and a third opening for exposing the metal foil through the first opening; and
forming, on the insulating resin, a first metal layer electrically connected to the metal foil through the first and third openings and a second metal layer electrically connected to the conductive polymer layer through the second opening.

10. An electronic circuit board comprising:
a substrate having wiring patterns; and
a semiconductor IC and the thin film capacitor as claimed in claim 1 provided on the substrate,
wherein the first and second electrodes of the thin film capacitor are connected to the semiconductor IC through the wiring patterns.
